(19) United States
(12) Patent Application Publication
(10) Pub. No.: US 2021/0360838 A1
(43) Pub. Date: Nov. 18, 2021

(54) COMPOSITE MATERIAL FOR SHIELDING OR ABSORBING ELECTROMAGNETIC WAVE AND METHOD FOR MANUFACTURING THE SAME

(71) Applicant: GET Green Energy Corp., Ltd., Tainan City (TW)

(72) Inventors: Wei-Jen Liu, Taoyuan City (TW); Hsi-Nien Ho, Taoyuan City (TW); I-Ting Hsieh, Taoyuan City (TW); Cheng-Che Hsieh, New Taipei City (TW); Yung-Liang Ke, Changhua County (TW); Yun Shuan Chu, Yilan County (TW)

(73) Assignee: GET Green Energy Corp., Ltd., Tainan City (TW)

(21) Appl. No.: 16/910,089

(22) Filed: Jun. 24, 2020

(30) Foreign Application Priority Data
May 13, 2020 (TW) 109115865

(51) Int. Cl. H05K 9/00

(52) U.S. Cl. CPC H05K 9/0081

(57) ABSTRACT

The present disclosure provides a composite material for shielding or absorbing an electromagnetic wave and a method for manufacturing the same. The composite material includes an electromagnetic absorbing material including a silicon carbide and a conductive material including a two-dimensional carbon material containing at least one of a graphite sheet and a graphene sheet.

### CROSS-REFERENCE TO RELATED APPLICATION

This application claims the priority benefits of Taiwan application serial no. 109115865, filed on May 13, 2020. The entirety of the above-mentioned patent application is hereby incorporated by reference herein and made a part of this specification.

### BACKGROUND OF THE INVENTION

### 1. Field of the Invention

The invention relates to a composite material and a method for manufacturing the same, and more particularly, to a composite material for shielding or absorbing an electromagnetic wave and a method for manufacturing the same.

### 2. Description of Related Art

With the increasing of the operation speed of electronic devices such as a smart phone, a tablet, and a laptop, noise generated from electronic components in the electronic devices has also increased accordingly. For example, the electronic components usually generate electromagnetic waves during its operation, and the electromagnetic waves may become noise to interfere with an antenna in the electronic device, such that the ability of the antenna to transmit and receive signals may decrease. Therefore, in many electronic devices, electromagnetic shielding or electromagnetic absorbing structures are provided on the electronic components to avoid the noise generated by the electromagnetic waves affecting the ability of the antenna to transmit and receive signals.

However, the higher performance of the electronic device is, the more of the noise generated from the electronic component will be. Therefore, how to effectively improve the efficiency for shielding or absorbing the electromagnetic waves is one of the problems that researchers in the field urgently want to solve.

### SUMMARY OF THE INVENTION

The invention provides a composite material and a method for manufacturing the same, which may have a good electromagnetic shielding or electromagnetic absorbing effect.

An embodiment of the invention provides a composite material for shielding or absorbing an electromagnetic wave. The composite material includes an electromagnetic absorbing material including a silicon carbide and a conductive material including a two-dimensional carbon material containing at least one of a graphite sheet and a graphene sheet.

According to an embodiment of the invention, the weight ratio of the conductive material and the electromagnetic absorbing material is ranging from 1:9 to 9:1.

According to an embodiment of the invention, the conductive material further includes a one-dimensional carbon material.

According to an embodiment of the invention, the weight ratio of the two-dimensional carbon material and the one-dimensional carbon material is ranging from 99:1 to 90:10.

According to an embodiment of the invention, the one-dimensional carbon material includes a carbon nanotube.

An embodiment of the invention provides a method for manufacturing a composite material for shielding or absorbing an electromagnetic wave. The method includes a step of mixing an electromagnetic absorbing material and a conductive material, wherein the electromagnetic absorbing material includes a silicon carbide, and the conductive material includes a two-dimensional carbon material containing at least one of a graphite sheet and a graphene sheet.

According to an embodiment of the invention, the weight ratio of the conductive material and the electromagnetic absorbing material is ranging from 1:9 to 9:1.

According to an embodiment of the invention, the graphene sheet is prepared by performing a cavitation process on a raw material of carbon in a liquid phase exfoliation.

According to an embodiment of the invention, a solvent used in the liquid phase exfoliation is one or more selected from the group consisting of water, ethanol, and NMP.

According to an embodiment of the invention, a solid content of the raw material of carbon in the solvent is ranging from 1 wt % to 10 wt %.

According to an embodiment of the invention, a number of times of performing the cavitation process in the liquid phase exfoliation is more than 1 time and less than 100 times.

According to an embodiment of the invention, the conductive material further includes a one-dimensional carbon material.

According to an embodiment of the invention, the weight ratio of the two-dimensional carbon material and the one-dimensional carbon material is ranging from 99:1 to 90:10.

According to an embodiment of the invention, the one-dimensional carbon material includes a carbon nanotube.

Based on the above, the silicon carbide included in the electromagnetic absorbing material may have advantages of high absorption and low reflectance for electromagnetic waves, and the two-dimensional carbon material containing at least one of the graphite sheet and graphene sheet may have good conductivity. Thereby, the composite material is not only able to absorb electromagnetic waves easily but also generates a conductive network inside the composite material, such that the electromagnetic waves absorbed into the composite material can be converted to a current having a same direction with the electric field due to polarization. Meanwhile, the current forms a closed current loop inside the composite material to generate an eddy current. As such, the electric energy converted from the electromagnetic waves can be further converted to a heat energy and then be consumed through heat transfer, so that the composite material may have a good electromagnetic shielding or electromagnetic absorbing effect.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a diagram illustrating the relationship between the frequency (Hz) and shielding effectiveness (dB) of Comparative Example 1 and Examples 1-5 in the X-band.

FIG. 1B is a diagram illustrating the relationship between the frequency (Hz) and shielding effectiveness (dB) of Comparative Example 1 and Examples 1-5 in the Ku-band.

FIG. 2A is a diagram illustrating the relationship between the frequency (Hz) and shielding effectiveness (dB) of Comparative Example 1 and Examples 6-10 in the X-band.

FIG. 2B is a diagram illustrating the relationship between the frequency (Hz) and shielding effectiveness (dB) of Comparative Example 1 and Examples 6-10 in the Ku-band.

FIG. 3A is a diagram illustrating the relationship between the frequency (Hz) and shielding effectiveness (dB) of Comparative Example 1 and Examples 11-15 in the X-band.

FIG. 3B is a diagram illustrating the relationship between the frequency (Hz) and shielding effectiveness (dB) of Comparative Example 1 and Examples 11-15 in the Ku-band.

### DESCRIPTION OF THE EMBODIMENTS

The present disclosure is more fully described with reference to the drawings of the embodiments. However, the present disclosure may be embodied in a variety of different forms and should not be limited to the embodiments described herein. The thickness of layers and regions in the drawings will be exaggerated for clarity. The same or similar reference numerals indicate the same or similar elements, and the following paragraphs will not be repeated.

It will be understood that when an element is referred to as being “on” or “connected” to another element, it may be directly on or connected to the other element or intervening elements may be present therebetween. If an element is referred to as being “directly on” or “directly connected” to another element, there are no intervening elements therebetween. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

A composite material for shielding or absorbing an electromagnetic wave may include an electromagnetic absorbing material and a conductive material, wherein the electromagnetic absorbing material may include a silicon carbide, and a conductive material may include a two-dimensional carbon material containing at least one of a graphite sheet and a graphene sheet. As such, the composite material is not only able to absorb electromagnetic waves easily, but also generates a conductive network inside the composite material, such that the electromagnetic waves absorbed into the composite material can be converted to a current having a same direction with the electric field due to polarization. Meanwhile, the current forms a closed current loop inside the composite material to generate an eddy current. Thereby, the electric energy converted from the electromagnetic waves can be further converted to a heat energy and then be consumed through heat transfer such as heat conduction, heat convection, or heat radiation, so that the composite material may have a good electromagnetic shielding or electromagnetic absorbing effect. In the present embodiment, the weight ratio of the conductive material and the electromagnetic absorbing material may be ranging from 1:9 to 9:1. In the present embodiment, a method for manufacturing the composite material for shielding or absorbing the electromagnetic waves may include mixing the electromagnetic absorbing material and the conductive material.

In the present embodiment, the silicon carbide may be obtained by performing following processes such as recycling, purifying, and separating on the silicon waste of the electronics industry. For example, the silicon carbide may be obtained by separating and purifying the waste of sliced wafer. In the present embodiment, the particle size of the silicon carbide may be about 0.1 μm to 100 μm. For example, the average particle size (D50) of the silicon carbide may be about 2.156 μm. In the present embodiment, the crystal structure of the silicon carbide may belong to the hexagonal structure.

In the present embodiment, the conductive material may be a two-dimensional carbon material containing a graphene sheet, so that the electromagnetic waves injected into the composite material may generate a multiple scattering caused by the high specific surface area and a structural characteristic of graphene. Thereby, the energy of the electromagnetic waves can be consumed and the purpose of absorbing the electromagnetic waves can be achieved. The graphene sheet may include a single-layer graphene, a few-layer graphene, a multi-layer graphene or a combination thereof. The “few-layer graphene” refers to graphene having more than 1 layer and less than 10 layers. The “multi-layer graphene” refers to graphene having 10 layers or more. The thickness of graphene may be about 2 nm to 10 nm.

In the present embodiment, the graphene sheet may be prepared by performing a cavitation process on a raw material of carbon in a liquid phase exfoliation. For example, the cavitation progress may be performed on the raw material of carbon by using a continuous cell disrupter. The raw material of carbon is instantly released at an outlet of the continuous cell disrupter in a high-pressure environment, causing the layers of raw material of carbon to be instantly peeled off so that the carbon in the layers of the raw material of carbon can be delaminated to form the graphene sheet. The pressure used in the liquid phase exfoliation may be, for example, more than 0 bar and less than 3000 bar. The number of times of performing the cavitation process in the liquid phase exfoliation may be more than 1 time and less than 100 times. In the present embodiment, the pressure used in each times of the cavitation processes in the liquid phase exfoliation may be different. The temperature used in the liquid phase exfoliation may be, for example, higher than 4° C. and lower than 50° C. In the present embodiment, a solvent used in the liquid phase exfoliation may be one or more selected from the group consisting of water, ethanol, and NMP. In the present embodiment, a solid content of the raw material of carbon in the solvent may be ranging from 1 wt % to 10 wt %.

In the present embodiment, the thickness of the graphene sheet, prepared by performing the cavitation process on the raw material of carbon in the liquid phase exfoliation, may be reduced to nanoscale, but the sheet size of the graphene sheet may be slightly smaller than the sheet size of the raw material of carbon. For example, as the graphite sheet with the sheet size (d₅₀) of about 11.145 μm is subjected to the above liquid phase exfoliation, the graphene sheet with the sheet size about 8.586 μm and the thickness about 2 nm can be obtained.

In some embodiments, the conductive material may further include a one-dimensional carbon material to further enhance the electromagnetic shielding or electromagnetic absorbing effect of the composite material. The one-dimensional carbon material may be, for example, a carbon nanotube. Hereinafter, the two-dimensional carbon material containing the graphene sheet will be used as the exemplary example for the conductive material, and the carbon nanotube will be used as the exemplary example for the one-dimensional carbon material included in the conductive material, but the invention is not limited thereto. In the case where the composite material includes a silicon carbide, one-dimensional fibrous carbon nanotubes, and two-dimensional graphene sheets, the gaps between the two-dimensional graphene sheets can be filled with the silicon carbide and the carbon nanotubes to form a denser conductive network, thereby the electromagnetic shielding or electromagnetic absorbing effect of the composite material can be enhanced.

In the present embodiment, the weight ratio of the two-dimensional carbon material and the one-dimensional carbon material may be ranging from 99:1 to 90:10, and more preferable from 99:1 to 95:5 to avoid the decrease of the electromagnetic shielding or electromagnetic absorbing effect resulting from the agglomeration phenomenon.

In some embodiments, the composite material may further include other additives according to the requirements. For example, the composite material may include a carbon black, an iron oxide, or a combination thereof.

In some embodiments, the composite material may further include an encapsulant or a supporting material, such as paraffin or epoxy resin, to prepare a composite bulk material for shielding or absorbing the electromagnetic waves. In the present embodiment, the electromagnetic absorbing material and the conductive material may be added to the encapsulant or the support material at a ratio of 10 wt % to 80 wt % based on the total weight of the encapsulant or the support material.

Features of the disclosure will be described more specifically below with reference to Example 1-15 and Comparative Example 1. Although the following Examples 1-15 are described, the used materials, their quantities and ratios, processing details, processing flow, and the like may be appropriately changed without departing from the scope of the disclosure. Therefore, the disclosure should not be interpreted restrictively by Examples 1-15 described below.

[The graphite sheet is used as the conductive material]

### Example 1

Firstly, 7.5 g of a paraffin is heated at 70° C. until the paraffin is completely melted. Then, 1.6875 g of a silicon carbide (SiC) and 0.1875 g of a graphite sheet are added to the melted paraffin and stirred (4000 rpm) with a homogenizer for 2 hours until the silicon carbide and the graphite sheet are homogeneously dispersed in the liquid paraffin solution. After that, the liquid paraffin solution is poured into a square mold of 3 cm×3 cm, and then subjects to a pressure forming process at 17000 lbf after solidification.

### Example 2

Firstly, 7.5 g of a paraffin is heated at 70° C. until the paraffin is completely melted. Then, 1.3125 g of a silicon carbide (SiC) and 0.5625 g of a graphite sheet are added to the melted paraffin and stirred (4000 rpm) with a homogenizer for 2 hours until the silicon carbide and the graphite sheet are homogeneously dispersed in the liquid paraffin solution. After that, the liquid paraffin solution is poured into a square mold of 3 cm×3 cm, and then subjects to a pressure forming process at 17000 lbf after solidification.

### Example 3

Firstly, 7.5 g of a paraffin is heated at 70° C. until the paraffin is completely melted. Then, 0.9375 g of a silicon carbide (SiC) and 0.9375 g of a graphite sheet are added to the melted paraffin and stirred (4000 rpm) with a homogenizer for 2 hours until the silicon carbide and the graphite sheet are homogeneously dispersed in the liquid paraffin solution. After that, the liquid paraffin solution is poured into a square mold of 3 cm×3 cm, and then subjects to a pressure forming process at 17000 lbf after solidification.

### Example 4

Firstly, 7.5 g of a paraffin is heated at 70° C. until the paraffin is completely melted. Then, 0.5625 g of a silicon carbide (SiC) and 1.3125 g of a graphite sheet are added to the melted paraffin and stirred with a homogenizer for 2 hours (4000 rpm) until the silicon carbide and the graphite sheet are homogeneously dispersed in the liquid paraffin solution. After that, the liquid paraffin solution is poured into a square mold of 3 cm×3 cm, and then subjects to a pressure forming process at 17000 lbf after solidification.

### Example 5

Firstly, 7.5 g of a paraffin is heated at 70° C. until the paraffin is completely melted. Then, 0.1875 g of a silicon carbide (SiC) and 1.6875 g of a graphite sheet are added to the melted paraffin and stirred with a homogenizer for 2 hours (4000 rpm) until the silicon carbide and the graphite sheet are homogeneously dispersed in the liquid paraffin solution. After that, the liquid paraffin solution is poured into a square mold of 3 cm×3 cm, and then subjects to a pressure forming process at 17000 lbf after solidification.

[The graphene sheet is used as the conductive material]

### Example 6

Firstly, 7.5 g of a paraffin is heated at 70° C. until the paraffin is completely melted. Then, 1.6875 g of a silicon carbide (SiC) and 0.1875 g of a graphene sheet are added to the melted paraffin and stirred (4000 rpm) with a homogenizer for 2 hours until the silicon carbide and the graphene sheet are homogeneously dispersed in the liquid paraffin solution. After that, the liquid paraffin solution is poured into a square mold of 3 cm×3 cm, and then subjects to a pressure forming process at 17000 lbf after solidification.

### Example 7

Firstly, 7.5 g of a paraffin is heated at 70° C. until the paraffin is completely melted. Then, 1.3125 g of a silicon carbide (SiC) and 0.5625 g of a graphene sheet are added to the melted paraffin and stirred (4000 rpm) with a homogenizer for 2 hours until the silicon carbide and the graphene sheet are homogeneously dispersed in the liquid paraffin solution. After that, the liquid paraffin solution is poured into a square mold of 3 cm×3 cm, and then subjects to a pressure forming process at 17000 lbf after solidification.

### Example 8

Firstly, 7.5 g of a paraffin is heated at 70° C. until the paraffin is completely melted. Then, 0.9375 g of a silicon carbide (SiC) and 0.9375 g of a graphene sheet are added to the melted paraffin and stirred (4000 rpm) with a homogenizer for 2 hours until the silicon carbide and the graphene sheet are homogeneously dispersed in the liquid paraffin solution. After that, the liquid paraffin solution is poured into a square mold of 3 cm×3 cm, and then subjects to a pressure forming process at 17000 lbf after solidification.

### Example 9

Firstly, 7.5 g of a paraffin is heated at 70° C. until the paraffin is completely melted. Then, 0.5625 g of a silicon carbide (SiC) and 1.3125 g of a graphene sheet are added to the melted paraffin and stirred (4000 rpm) with a homogenizer for 2 hours until the silicon carbide and the graphene sheet are homogeneously dispersed in the liquid paraffin solution. After that, the liquid paraffin solution is poured into a square mold of 3 cm×3 cm, and then subjects to a pressure forming process at 17000 lbf after solidification.

### Example 10

Firstly, 7.5 g of a paraffin is heated at 70° C. until the paraffin is completely melted. Then, 0.1875 g of a silicon carbide (SiC) and 1.6875 g of a graphene sheet are added to the melted paraffin and stirred (4000 rpm) with a homogenizer for 2 hours until the silicon carbide and the graphene sheet are homogeneously dispersed in the liquid paraffin solution. After that, the liquid paraffin solution is poured into a square mold of 3 cm×3 cm, and then subjects to a pressure forming process at 17000 lbf after solidification.

[The graphene sheet/carbon nanotube is used as the conductive material]

### Example 11

Firstly, 7.5 g of a paraffin is heated at 70° C. until the paraffin is completely melted. Then, 0.1875 g of a silicon carbide (SiC), 1.670625 g of a graphene sheet, and 0.016875 g of a carbon nanotube are added to the melted paraffin and stirred (4000 rpm) with a homogenizer for 2 hours until the silicon carbide, the graphene sheet, and the carbon nanotube are homogeneously dispersed in the liquid paraffin solution. After that, the liquid paraffin solution is poured into a square mold of 3 cm×3 cm, and then subjects to a pressure forming process at 17000 lbf after solidification.

### Example 12

Firstly, 7.5 g of a paraffin is heated at 70° C. until the paraffin is completely melted. Then, 0.1875 g of a silicon carbide (SiC), 1.65375 g of a graphene sheet, and 0.03375 g of a carbon nanotube are added to the melted paraffin and stirred (4000 rpm) with a homogenizer for 2 hours until the silicon carbide, the graphene sheet, and the carbon nanotube are homogeneously dispersed in the liquid paraffin solution. After that, the liquid paraffin solution is poured into a square mold of 3 cm×3 cm, and then subjects to a pressure forming process at 17000 lbf after solidification.

### Example 13

Firstly, 7.5 g of a paraffin is heated at 70° C. until the paraffin is completely melted. Then, 0.1875 g of a silicon carbide (SiC), 1.636875 g of a graphene sheet, and 0.050625 g of a carbon nanotube are added to the melted paraffin and stirred (4000 rpm) with a homogenizer for 2 hours until the silicon carbide, the graphene sheet, and the carbon nanotube are homogeneously dispersed in the liquid paraffin solution. After that, the liquid paraffin solution is poured into a square mold of 3 cm×3 cm, and then subjects to a pressure forming process at 17000 lbf after solidification.

### Example 14

Firstly, 7.5 g of a paraffin is heated at 70° C. until the paraffin is completely melted. Then, 0.1875 g of a silicon carbide (SiC), 1.62 g of a graphene sheet, and 0.0675 g of a carbon nanotube are added to the melted paraffin and stirred (4000 rpm) with a homogenizer for 2 hours until the silicon carbide, the graphene sheet, and the carbon nanotube are homogeneously dispersed in the liquid paraffin solution. After that, the liquid paraffin solution is poured into a square mold of 3 cm×3 cm, and then subjects to a pressure forming process at 17000 lbf after solidification.

### Example 15

Firstly, 7.5 g of a paraffin is heated at 70° C. until the paraffin is completely melted. Then, 0.1875 g of a silicon carbide (SiC), 1.603125 g of a graphene sheet, and 0.084375 g of a carbon nanotube are added to the melted paraffin and stirred (4000 rpm) with a homogenizer for 2 hours until the silicon carbide, the graphene sheet, and the carbon nanotube are homogeneously dispersed in the liquid paraffin solution. After that, the liquid paraffin solution is poured into a square mold of 3 cm×3 cm, and then subjects to a pressure forming process at 17000 lbf after solidification.

### Comparative Example 1

Firstly, 7.5 g of a paraffin is heated at 70° C. until the paraffin is completely melted. Then, 1.875 g of a silicon carbide (SiC) is added to the melted paraffin and stirred (3000 rpm) with a homogenizer for 2 hours until the silicon carbide is homogeneously dispersed in the liquid paraffin solution. After that, the liquid paraffin solution is poured into a square mold of 3 cm×3 cm, and then subjects to a pressure forming process at 17000 lbf after solidification.

The above Examples 1-15 and Comparative Example 1 are arranged in the Table 1 below.

TABLE 1

| | | | Weight ratio | |
|---|---|---|---|---|
| | | | Two- | |
| | | | dimensional | Conductive |
| | | | carbon | mate- |
| | | Electro- | material:one- | rial:elec- |
| | | magnetic | dimensional | tromagnetic |
| | Conductive | absorbing | carbon | absorbing |
| | material | material | material | material |
| Comparative | — | SiC | — | — |
| Example 1 | | | | |
| Example 1 | Graphite sheet | SiC | — | 1:9 |
| Example 2 | Graphite sheet | SiC | — | 3:7 |
| Example 3 | Graphite sheet | SiC | — | 5:5 |
| Example 4 | Graphite sheet | SiC | — | 7:3 |
| Example 5 | Graphite sheet | SiC | — | 1:9 |
| Example 6 | Graphene sheet | SiC | — | 9:1 |
| Example 7 | Graphene sheet | SiC | — | 3:7 |
| Example 8 | Graphene sheet | SiC | — | 5:5 |
| Example 9 | Graphene sheet | SiC | — | 7:3 |
| Example 10 | Graphene sheet | SiC | — | 9:1 |
| Example 11 | Graphene sheet/ | SiC | 99:1 | 9:1 |
| | Carbon nanotube | | | |
| Example 12 | Graphene sheet/ | SiC | 98:2 | 9:1 |
| | Carbon nanotube | | | |
| Example 13 | Graphene sheet/ | SiC | 97:3 | 9:1 |
| | Carbon nanotube | | | |
| Example 14 | Graphene sheet/ | SiC | 96:4 | 9:1 |
| | Carbon nanotube | | | |
| Example 15 | Graphene sheet/ | SiC | 95:5 | 9:1 |
| | Carbon nanotube | | | |

### Experiment 1

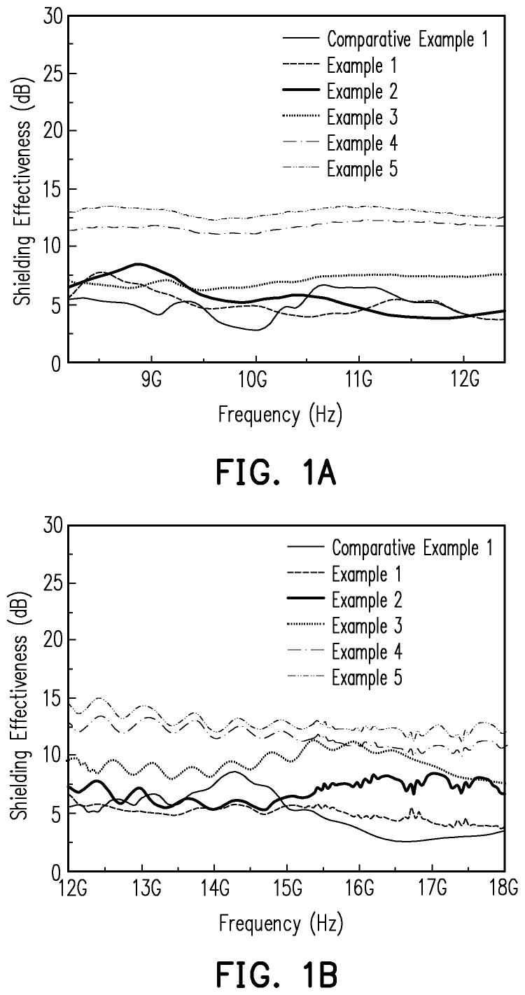

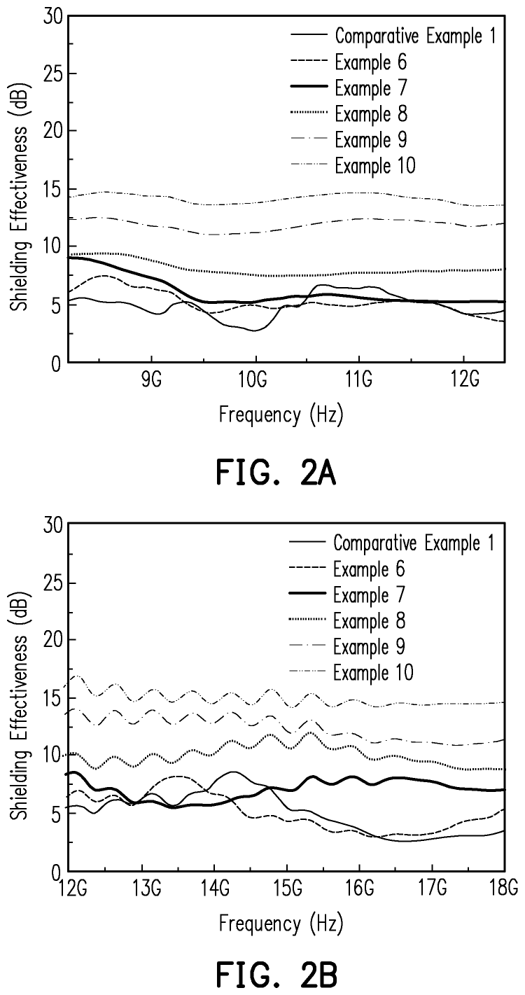

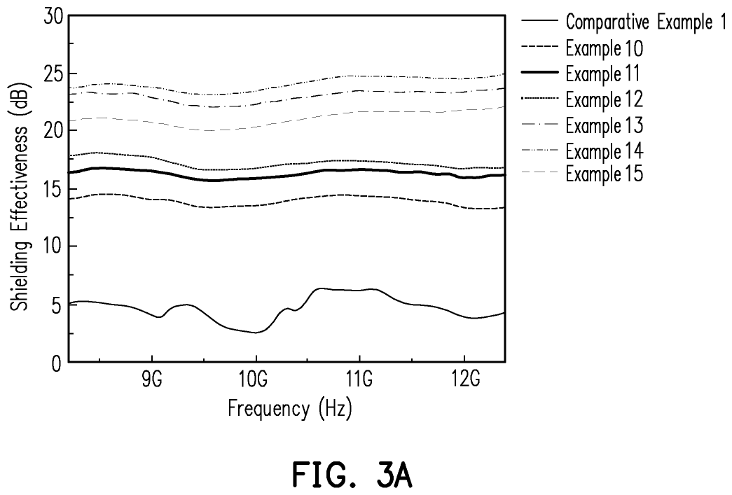

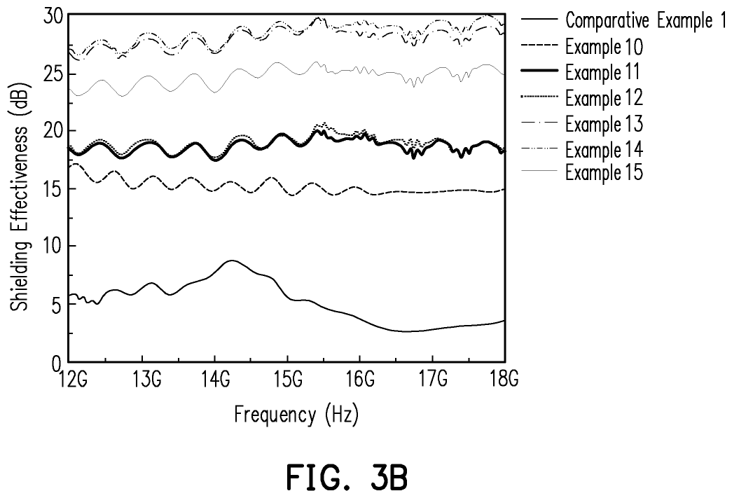

The Examples 1-15 are subjected to a test for electromagnetic shielding effectiveness. The shielding effectiveness in X-band is shown in FIG. 1A, FIG. 2A, and FIG. 3A, and the data of the shielding effectiveness in X-band is arranged in the following Table 2. The shielding effectiveness in Ku-band is shown in FIG. 1B, FIG. 2B, and FIG. 3B and the data of the shielding effectiveness in Ku-band is arranged in the following Table 3. FIG. 1A is a diagram illustrating the relationship between the frequency (Hz) and shielding effectiveness (dB) of Comparative Example 1 and Examples 1-5 in the X-band. FIG. 1B is a diagram illustrating the relationship between the frequency (Hz) and shielding effectiveness (dB) of Comparative Example 1 and Examples 1-5 in the Ku-band. FIG. 2A is a diagram illustrating the relationship between the frequency (Hz) and shielding effectiveness (dB) of Comparative Example 1 and Examples 6-10 in the X-band. FIG. 2B is a diagram illustrating the relationship between the frequency (Hz) and shielding effectiveness (dB) of Comparative Example 1 and Examples 6-10 in the Ku-band. FIG. 3A is a diagram illustrating the relationship between the frequency (Hz) and shielding effectiveness (dB) of Comparative Example 1 and Examples 11-15 in the X-band. FIG. 3B is a diagram illustrating the relationship between the frequency (Hz) and shielding effectiveness (dB) of Comparative Example 1 and Examples 11-15 in the Ku-band.

TABLE 2

| | Shielding effectiveness in X-band (dB) | | | | | |
|---|---|---|---|---|---|---|
| | 8.2 | 9.04 | 9.88 | 10.72 | 11.56 | 12.4 |
| | GHz | GHz | GHz | GHz | GHz | GHz |
| Comparative | 4.72 | 4.03 | 2.81 | 6.55 | 5.08 | 4.52 |
| Example 1 | | | | | | |
| Example 1 | 5.05 | 5.90 | 4.73 | 4.16 | 5.13 | 3.64 |
| Example 2 | 6.19 | 7.97 | 5.14 | 5.40 | 3.99 | 4.55 |
| Example 3 | 6.78 | 6.96 | 6.41 | 7.59 | 7.54 | 7.89 |
| Example 4 | 11.05 | 11.62 | 11.00 | 12.15 | 12.08 | 11.70 |
| Example 5 | 12.61 | 12.98 | 12.25 | 13.37 | 12.95 | 12.41 |
| Example 6 | 5.52 | 6.01 | 4.71 | 4.91 | 5.00 | 3.40 |
| Example 7 | 8.68 | 6.99 | 5.13 | 5.89 | 5.31 | 5.36 |
| Example 8 | 9.07 | 8.59 | 7.50 | 7.64 | 7.86 | 8.18 |
| Example 9 | 11.96 | 11.57 | 10.87 | 12.02 | 12.04 | 11.81 |
| Example 10 | 13.88 | 14.02 | 13.40 | 14.46 | 14.00 | 13.40 |
| Example 11 | 16.17 | 16.48 | 15.77 | 16.69 | 16.42 | 16.25 |
| Example 12 | 17.67 | 17.58 | 16.62 | 17.45 | 17.05 | 16.94 |
| Example 13 | 23.04 | 22.85 | 22.13 | 23.33 | 23.41 | 23.71 |
| Example 14 | 23.43 | 23.63 | 23.24 | 24.62 | 24.65 | 24.89 |
| Example 15 | 20.63 | 20.65 | 20.14 | 21.46 | 21.68 | 22.14 |

TABLE 3

| | Shielding effectiveness in Ku-band (dB) | | | | | |
|---|---|---|---|---|---|---|
| | 12 | 13.2 | 14.4 | 15.6 | 16.8 | 18 |
| | GHz | GHz | GHz | GHz | GHz | GHz |
| Comparative | 5.58 | 6.67 | 8.30 | 4.41 | 2.64 | 3.53 |
| Example 1 | | | | | | |
| Example 1 | 6.59 | 4.97 | 5.58 | 5.44 | 5.19 | 3.97 |
| Example 2 | 7.28 | 5.74 | 5.89 | 7.48 | 7.96 | 6.67 |
| Example 3 | 9.69 | 9.28 | 9.16 | 10.51 | 9.53 | 7.60 |
| Example 4 | 12.82 | 13.12 | 12.44 | 11.33 | 10.73 | 10.78 |
| Example 5 | 14.46 | 13.78 | 13.02 | 12.53 | 12.25 | 12.02 |
| Example 6 | 6.52 | 7.47 | 5.20 | 3.43 | 3.16 | 5.39 |
| Example 7 | 8.45 | 6.03 | 6.47 | 7.50 | 7.90 | 7.12 |
| Example 8 | 10.02 | 10.14 | 10.98 | 10.60 | 9.57 | 8.85 |
| Example 9 | 13.68 | 13.87 | 13.10 | 11.77 | 11.21 | 11.43 |
| Example 10 | 16.19 | 15.77 | 14.88 | 14.21 | 14.40 | 14.64 |
| Example 11 | 18.65 | 18.75 | 19.26 | 19.89 | 18.96 | 18.13 |
| Example 12 | 18.32 | 18.57 | 18.84 | 19.09 | 18.13 | 17.81 |
| Example 13 | 26.43 | 27.35 | 28.24 | 28.38 | 27.71 | 27.72 |
| Example 14 | 26.81 | 27.91 | 28.46 | 28.67 | 28.25 | 28.67 |
| Example 15 | 23.31 | 24.18 | 24.87 | 24.73 | 24.33 | 24.54 |

Referring to Table 2 and Table 3, with the increasing of the ratio of the two-dimensional material (e.g., graphite sheet or graphene sheet) in the composite material, the electromagnetic shielding effectiveness is increased accordingly. In addition, as compared with the shielding effectiveness results of Example 5 and Example 10, the two-dimensional graphene sheet used as the conductive material has the better shielding effectiveness. Moreover, as compared with the shielding effectiveness results of Example 10 and Examples 11-15, a combination of the two-dimensional graphene sheet and the one-dimensional carbon nanotube as the conductive material has the better shielding effectiveness. Furthermore, as compared with the shielding effectiveness results of Example 11 to Example 14, with the increasing of the ratio of the one-dimensional carbon nanotube in the conductive material, the electromagnetic shielding effectiveness is increased accordingly. However, please refers to the shielding effectiveness result shown in Example 15, when the ratio of the one-dimensional carbon nanotube in the conductive material is too high, the shielding effectiveness will be decreased due to agglomeration phenomenon.

In summary, in the composite material and the method for manufacturing the same according to an embodiment of the present invention, the silicon carbide included in the electromagnetic absorbing material may have advantages of high absorption and low reflectance for electromagnetic waves, and the two-dimensional carbon material containing at least one of the graphite sheet and graphene sheet may have good conductivity. Thereby, the composite material is not only able to absorb electromagnetic waves easily but also generates a conductive network inside the composite material, such that the electromagnetic waves absorbed into the composite material can be converted to a current having a same direction with the electric field due to polarization. Meanwhile, the current forms a closed current loop inside the composite material to generate an eddy current. As such, the electric energy converted from the electromagnetic waves can be further converted to a heat energy and then be consumed through heat transfer, so that the composite material may have a good electromagnetic shielding or electromagnetic absorbing effect.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A composite material for shielding or absorbing an electromagnetic wave, and the composite material comprising:
an electromagnetic absorbing material comprising a silicon carbide; and
a conductive material comprising a two-dimensional carbon material containing at least one of a graphite sheet and a graphene sheet.

2. The composite material according to claim 1, wherein the weight ratio of the conductive material and the electromagnetic absorbing material is ranging from 1:9 to 9:1.

3. The composite material according to claim 1, wherein the conductive material further comprises a one-dimensional carbon material.

4. The composite material according to claim 3, wherein the weight ratio of the two-dimensional carbon material and the one-dimensional carbon material is ranging from 99:1 to 90:10.

5. The composite material according to claim 3, wherein the one-dimensional carbon material comprises a carbon nanotube.

6. A method for manufacturing a composite material for shielding or absorbing an electromagnetic wave, and the method comprising:
mixing an electromagnetic absorbing material and a conductive material,
wherein the electromagnetic absorbing material comprises a silicon carbide, and the conductive material comprises a two-dimensional carbon material containing at least one of a graphite sheet and a graphene sheet.

7. The method according to claim 6, wherein the weight ratio of the conductive material and the electromagnetic absorbing material is ranging from 1:9 to 9:1.

8. The method according to claim 6, wherein the graphene sheet is prepared by performing a cavitation process on a raw material of carbon in a liquid phase exfoliation.

9. The method according to claim 8, wherein a solvent used in the liquid phase exfoliation is one or more selected from the group consisting of water, ethanol, and NMP.

10. The method according to claim 9, wherein a solid content of the raw material of carbon in the solvent is ranging from 1 wt % to 10 wt %.

11. The method according to claim 8, wherein a number of times of performing the cavitation process in the liquid phase exfoliation is more than 1 time and less than 100 times.

12. The method according to claim 6, wherein the conductive material further comprises a one-dimensional carbon material.

13. The method according to claim 12, wherein the weight ratio of the two-dimensional carbon material and the one-dimensional carbon material is ranging from 99:1 to 90:10.

14. The method according to claim 12, wherein the one-dimensional carbon material comprises a carbon nanotube.
